(19) United States
(12) Patent Application Publication
(10) Pub. No.: US 2011/0185265 A1
(43) Pub. Date: Jul. 28, 2011

(54) High-speed and agile encoder for variable strength long BCH codes

(75) Inventor: Raghunath Cherukuri, Richardson, TX (US)

(73) Assignee: RAGHUNATH CHERUKURI, Richardson, TX (US)

(21) Appl. No.: 12/930,530

(22) Filed: Jan. 10, 2011

Related U.S. Application Data
(60) Provisional application No. 61/336,775, filed on Jan. 27, 2010.

(51) Int. Cl. H03M 13/15; G06F 11/10

(52) U.S. Cl. 714/782; 714/E11.033

(57) ABSTRACT

Agile BCH encoders are useful when the noise characteristics of the channel change which demands that the strength of the error correcting BCH code to be a variable. An agile encoder for encoding a linear cyclic code such as a BCH code, is a code that switches code strength (depth) relatively quickly in unit increments. The generator polynomial for the BCH code is provided in the factored form. The number of factored polynomials (minimal polynomials) chosen by the system determines the strength of the BCH code. The strength can vary from a weak code to a strong code in unit increments without a penalty on storage requirements for storing the factored polynomials. The BCH codeword is formed by a dividing network and a combining network. Special method is described that provides a trade off mechanism between latency and throughput while simultaneously optimizing the delay in the critical path which is in the forward path. Speed enhancements at minimal polynomial level are also provided by retiming, loop unfolding, loop unrolling, and special mathematical transformations. The presented invention can be implemented as an apparatus using software or hardware or in integrated circuit form.

### CROSS-REFERENCE TO RELATED APPLICATION

This application claims priority to, and the benefit of, U.S. Provisional Patent Application entitled, “HIGH SPEED AND AGILE LONG BCH ENCODER”, having Ser. No. U.S. 61/336,775, filed on Jan. 27, 2010.

### TECHNICAL FIELD

The present invention generally refers to novel encoder methods for Bose-Chaudhuri-Hocquenghen (BCH) codes.

### BACKGROUND OF THE INVENTION

Error correction codes are in wide use in almost all digital communications. This is due to the higher performance that the market demands for communicating over noisy channels. BCH codes which are a very important family of block codes that can be decoded using algebraic techniques with affordable complexity, have been in wide use for decades, especially in storage channels in various forms such as either Hamming codes or as Reed-Solomon (RS) codes. BCH codes are in wide use in concatenated coding techniques along with Convolutional codes or with other block codes such as Low-density parity check (LDPC) codes. Second generation Digital Video Broadcast (DVB) standards are adopting BCH codes as part of their concatenated coded strategy. Binary BCH codes have some advantages over RS codes, especially if the noise is a random noise. The read channel in a Multi-level per cell (MLC) based FLASH memory exhibits a random noise channel and BCH is a favorite code for error correction in FLASH memory products.

It is well known in coding theory that, the performance of a code improves as the length of the message increases. This is one of the reasons why there is a trend in high performance communication to use message length greater than 2¹⁴ bits (as specified in DVB-S2). It is also very common, that the application may demand varying error correction capabilities, the reason may be a change in the packet length or a change in the noise statistics. These reasons point to the need and practice of strength adaptive (agile) long BCH codes.

To correct t number of errors, a BCH code is typically implemented in systematic form. In a systematic form, a BCH code is obtained by dividing the message polynomial with the generator polynomial and then appending the remainder with the message to form the codeword polynomial. The generator polynomial is formed by taking the least-common multiple (LCM) of all the minimal polynomials corresponding to the 2t roots. The division is typically implemented using a Linear Feedback Shift-Register (LFSR) architecture. In a serial LFSR architecture, the feedback signal is required to drive all the XOR gates in the LFSR, as part of the polynomial reduction operation, built into the division operation. When the divisor polynomial g(x) is implemented in the expanded form, the degree of g(x) can be very high, and the fan-out of the feedback signal is so large that the throughput is constrained by this load.

Despite the fact that the long BCH code has fan-out bottleneck, the application demands high performance. This should be achieved by eliminating or reducing the fan-out bottleneck, processing more message samples (in parallel) and making the architecture agile and efficient to switch between packets and various values of t. Some typical implementation issues relating to BCH encoders are discussed in the next paragraphs.

Retiming and Loop unfolding can be used to reduce the fan-out bottleneck, but this method is typically design intensive. Unfolding can be combined with retiming to transform the LFSR to accept parallel input data. Although further speedup can been achieved in using this method, it is quite cumbersome at the design stage. Both these techniques involve pre and post processing using a new polynomial p(x) that needs to be identified through exhaustive searching based on clustered look-ahead computation. The overhead may be justified if the solution will be targeted for gigabits per second or higher throughputs. Parallelism can be achieved by simple loop unrolling. Parallelism can also be achieved using state-space design methods as has been shown while realizing a parallel cyclic redundancy check (CRC) implementation. This method involves pre-computations and storing of matrices of large dimensions.

In another possible solution, the given message is first divided by the minimal polynomials in parallel, and then the resulting remainders are all combined in a weighted fashion based on the Chinese Remainder theorem (CRT). The weighting polynomials need to be pre-computed using Euclid's multiplicative inverse algorithm. Further, these polynomials need to be stored in the memory. The area overhead is more than t times that of the LFSR corresponding to g(x) polynomial. Since the division is done by the minimal polynomials, the fan-out is upper bounded by m=log N. The encoder architecture based on CRT is an agile architecture, although at a higher cost of complexity and latency. Another competing agile architecture is that proposed by Pilsl, although further speed enhancements at minimal polynomial level and optimization of the feed-forward path are left unsolved.

Thus, there is a need for an encoder, whose complexity is less than the encoder based on CRT, and similar to an LFSR based implementation in terms of performance metrics such as throughput and latency and encoder which is more agile and offering higher speeds of operation than the above mentioned solutions. This invention addresses those needs.

### SUMMARY OF THE INVENTION

A high-speed BCH encoder that can change the ECC depth check, in increments of one (agile) at no additional cost or minimal cost is highly desired when the noise mechanisms in the channel vary over a wide range. A BCH code is formed by dividing the information polynomial by the generator polynomial. When the techniques available in the prior art are used, there are few problems, four of the dominant problems worth mentioning that reduce the speed of the encoder and increase the complexity are a) the generator polynomial for each ECC depth check (or the strength of the code) needs to be stored b) strength variation in steps of one is not possible without increasing the complexity c) critical path is in the feedback path that slows down the speed of operation and d) feed-forward path that becomes dominant when the feedback path is minimized. For a chosen strength of the code, lower values can not be accommodated when techniques from prior art are used. The present invention provides a solution to provide variable strength in increments of one, for all values less than and including t, where t is the strength of the BCH code, while simultaneously bounding the critical path in the feedback to a value of log N. In one embodiment of the invention, the solution comes at no additional cost in latency or throughput. Further speed-up is achieved by special provisions in the forward path to minimize the critical path in the forward path. In this embodiment of the invention, a trade-off between latency and throughput is provided to address various application needs. Even further speed-up is achieved by using mathematical or circuit transformations (such as retiming and/or unfolding) at the minimal polynomial level.

### BRIEF DESCRIPTION OF THE DRAWINGS

The following description with reference to the drawings will help to understand the invention in some but not limiting embodiments.

FIG. 1 depicts a typical implementation of a BCH encoder using a Linear Feedback Shift Register (LFSR).

FIG. 2 is an embodiment of the invention, showing a division network and a multiplication and combining network.

FIG. 3 is an embodiment of the invention, showing a division network by the minimal polynomials and a multiplication and combining network by the minimal polynomials.

FIG. 4 is an embodiment in accordance with the invention, showing a realization of the division network using LFSRs.

FIG. 5 depicts a typical implementation of a polynomial multiplier in GF(2) using a Linear Shift Register (LSR).

FIG. 6 is an embodiment in accordance with the invention, showing a realization of the multiplication network using LSRs.

FIGS. 7a-7c detail specific embodiments of the quotient generator in accordance with the invention.

FIG. 8 is an embodiment in accordance with the invention showing a realization of polynomial division using a LFSR with unrolled input and output.

FIG. 9 is an embodiment in accordance with the invention showing a realization of polynomial multiplication using a LFSR with unrolled input and output.

### DETAILED DESCRIPTION OF THE INVENTION

The invention will be described in detail with reference to exemplary embodiments and to accompanying drawings that form a part hereof. These embodiments illustrate in which the invention can be practiced. These embodiments are described in sufficient detail to enable those skilled in the art to practice the invention, and it is to be understood that other embodiments may be used and that any changes, logical, electrical and mechanical, may be made without departing from the scope and spirit of the present invention. The detailed description, therefore not to be taken in a limiting sense, and the scope of the present invention is defined only by the claims and equivalents thereof.

A general reference to coding and decoding techniques related to BCH codes is the book by Shu Lin and Daniel J Costello, Jr., entitled “Error Control Coding”, published by Prentice Hall, 2004. The next paragraph makes reference to this book.

In this paragraph the basic mathematics that defines a BCH code will be described. A k-bit message (u₀, u₁, u₂, uₖ₋₁) can be protected by a BCH code to protect up to t random bit errors by adding up to m·t redundant bits to form an n-bit long codeword (c₀, c₁, C₂, where n=2^{m-1}. The binary message and code bits uᵢ and cⱼ are from GF(2) and can form the coefficients of the polynomials of degree (k−1) and (n−1) respectively. The systematic encoding is performed by c(x)=u(x)·x^{(n-k)}+r(x) where r(x)=Rem(u(x)·x^{(n-k)})_{g(x)} or u(x)·x^{(n-k)}=q(x)·g(x)+r(x). Here g(x) is the generator polynomial to be specified, r(x) is the remainder polynomial resulting from the polynomial division of u(x)·x^{(n-k)} by g(x) and q(x) is the quotient from the division. Let α be a primitive root from the extended field GF(2^{m}) formed by using a primitive polynomial p(x). Then the generator polynomial g(x) is the lowest-degree polynomial over GF(2) that has (α, α², α³, α⁴, . . . α^{2t}) as its roots. Let mᵢ be the minimal polynomial of αⁱ, and since every even power of α can be expressed as some preceding odd power of α, then g(x) must be the LCM of all the odd minimal polynomials, which can be given as g(x)=LCM(m₁, m₃, m₅, . . . m₍₂ₜ₋₁₎).

The weight of a polynomial is defined as the number of non-zero elements in the polynomial. To correct t errors, the first t polynomials are multiplied to obtain g(x). As an example, the DVB-S2 standard specifies, a packet length of n=64800, with error correction capability t of 8, 10 or 12. The generator polynomials for each case will have a degree and weights of (128, 69), (160, 79) and (192, 85). In general the weight of a minimal polynomial gᵢ(x) is bounded by deg(gᵢ(x)). The order of the minimal polynomial defined in the extended field GF(2^{m}) formed by the primitive polynomial can be m. Since the generator polynomial g(x), for a desired code that can correct t errors, is the LCM of t minimal polynomials, the order of the generator polynomial g(x) is bounded to be m·t.

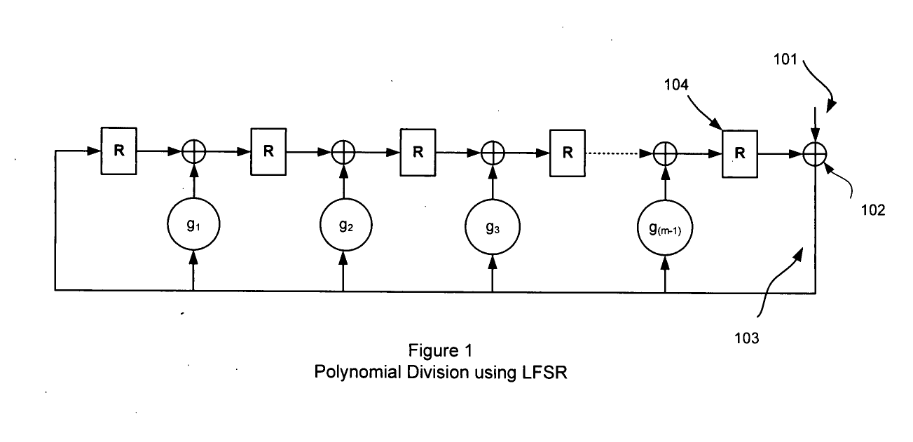

In this paragraph the classical architecture for encoding a BCH code described in the previous paragraph will be given. The architecture of such a systematic BCH encoder using LFSR is as shown in FIG. 1. Here gᵢ is the coefficient of the generator polynomial. The message 101 upon its availability will be logically combined in the XOR gate 102, with the MSB stored in the register element 104, to produce the feedback signal 103. The feedback signal determines whether the register update involves a polynomial reduction by the amount stored in the generator polynomial register. This reduction operation is performed in the XOR gates depicted in FIG. 1. Upon the completion of the operation, the result will be stored in the register elements. The feedback signal is also the quotient in the division operation. In this architecture, there is no use for the quotient and is not saved. At the end of k clock cycles, the state of the LFSR is the remainder and is shifted out as the tail bits to the message, to form the parity bits that define the code. At each clock the feedback signal is generated and has to drive all the summing nodes to perform the polynomial reduction. The fan-out of this signal sets the clock period of this architecture. As described in the previous paragraph, the fan-out can be up to mt. This fan-out bottleneck is the major problem of the classical architecture that substantially affects the speed of operation.

The fan-out problem of the classical architecture is illustrated in the above paragraph in the context of the DVB-S2. Similar contexts can be found easily, for those skilled in the art of designing high speed BCH encoder decoder circuits in other application contexts such as MLC FLASH Memory, HDMI and Optical communication areas. Solving the fan-out problem of the classical architecture for BCH encoders is an important goal for this invention. Some solutions are explained in the following.

Retiming and loop unfolding is used to reduce the fan-out bottleneck, as is described by K. K. Parhi in “Eliminating the fan-out bottleneck in parallel long BCH encoders”, IEEE Transaction on Circuits and Systems part I, vol. 51, no. 3, pp 512-516, March 2004. Unfolding is combined with re-timing, to transform the LFSR to accept parallel data. This method involves pre and post processing of the given data using a new polynomial p(x) that needs to be identified through exhaustive computer searching, based on clustered look-ahead computations. The overhead during design phase and during operational phase is justified since the target speed is Giga bits per second.

By using similar techniques for finding the polynomial p(x), Zhang et al, improved the speed of operation which they described in X. Zhang et al, “High-speed architectures for parallel long BCH encoders”, IEEE Transactions on VLSI Systems, vol. 13, no. 7, pp. 872-877, July 2005. The disadvantage again is the extra processing steps before and after encoding operation. A clear disadvantage due to these operations is the increase in the power consumption of the encoder, when the encoder is realized as an electronic circuit.

Throughput is increased in the work described by R. Micheloni et al., in “A 4 Gb 2b/cell NAND flash memory with embedded 5b BCH ECC for 36 MB/s system read throughput”, IEEE Solid-State Circuits Conference, pp. 497-506, February 2006. The increase in throughput is achieved by simple loop unrolling. The fan-out bottleneck is left unsolved.

Improvement in throughput without solving the problem of fan-out bottleneck, can also be done using state-space design methods that were described by G. Campobello et al., in “Parallel CRC realization,” IEEE Transactions on Computers, vol. 52, no. 10, pp. 1312-1319, October 2003. This particular method involves pre-computations and storage of large matrices, which is an added penalty on computing and storage resources.

A BCH encoder based on Chinese Remainder theorem (CRT) will be described in this paragraph. The BCH encoder based on CRT is proposed by H. Chen in the paper titled “CRT-Based High-Speed Parallel Architecture for long BCH Encoding”, IEEE Transactions on Circuits and Systems II, Vol. 56, No. 8, pp. 684-686. For every gᵢ(x) for all i=1, 2, . . . t in GF(2), there is a polynomial g′ᵢ(x) such that g′ᵢ(x)=g(x)/gᵢ(x). There is another polynomial g″ᵢ(x) such that g″ᵢ(x)·g′ᵢ(x)=1 mod gᵢ(x). Then g″ᵢ(x) is the multiplicative inverse of g′ᵢ(x) congruent to gᵢ(x) and such a multiplicative inverse can be obtained using extended Euclidean algorithm. Then according to CRT, Rem(u(x)·x^{(hu n-k)})_{g(x)} can be given as

Σ_{(i=1,2, . . . t)}{g′ᵢ(x)Rem(g″ᵢ(x)·u(x)·x^{(n-k)})gᵢ(x)}

As is evident form the mathematical description given above, there is a pre-computation during design phase to find the multiplicative inverses of the g′ᵢ(x), pre-computation of e(x) itself and storing these polynomials, in addition to storing all the gᵢ(x)s. Then there is pre-processing (multiplication by LFSR) of the message with g″ᵢ(x)s, before actual division. The division is carried in parallel using LFSRs and the remainders are combined (addition) after properly weighted (multiplied using LFSR) by the g′ᵢ(x)s. The clock speed is constrained by the fan-out of the LFSR during division and is thus bounded by m. There are several disadvantages with the encoder based on CRT. The pre-multiplication increases the data length by the degree of g″ᵢ(x) which can be at least m. The divider needs to process these extra bits, and thus the latency increases. Clocking issues are not simple but can be worked out. The hardware complexity is t times the m·t, since there are t parallel branches. A point to make here is that, the architecture is still input bit serial and throughput is that of any serial LFSR architecture. An advantage worth mentioning is strength adaptation is simple, only if the relevant polynomials are pre-computed during design phase. The architecture based on CRT divides the feedback path with a fan-out of m·t into t disconnected feedback paths each with fan-out bounded by m.

Pilsl describes an encoder for BCH codes that solves the critical path in the feedback path by keeping the generator polynomial in factored form. The encoder is slowed by the critical path in the feed-forward path of quotient propagation and this critical path in the feed-forward path is left unsolved. Further speed improvements at the minimal polynomial level through retiming and unfolding or any other mathematical or circuit transformations are not mentioned.

The present invention, draws inspiration from all the above methods and offers a solution to solve the fan-out bottleneck. In addition, the present invention, offers programmability in t by unit increments, and also solves the critical path in the forward path. Additional speed enhancements are achieved using retiming or unfolding methods. In order to fully explain the invention, the mathematical formulation is described first in the following.

The invention in one embodiment is described in this paragraph. The generator polynomial g(x) for the BCH code, which is described in an earlier paragraph, is the LCM of t minimal polynomials. In the present invention the generator polynomial g(x) is left in the factored form, instead of in the expanded polynomial form of degree m·t. The t minimal polynomials are stored in memory 203. In the present invention, the generator polynomial g(x) will not be stored, hence the storage requirements for the present invention are the same as the prior art based on classical method. The presented invention can correct errors ranging from 1 to t. Based on the channel characteristics or application demands, the system chooses a value for t. In prior art, based on classical method, the message polynomial u(x) will be divided by the generator polynomial g(x). In the present invention the message polynomial 201 will not be divided by g(x), instead there will be a series of successive divisions that will be described as follows.

Pre-multiplication of the message by x^{(n-k)} is distributed over t divisions, based on the observation that x^{(n-k)}=x^{m}, x^{m}, x^{m} . . . x^{m} (t terms)=x^{mt} (n−k=mt). The message u(x) pre-multiplied by x^{m}, is then divided by minimal polynomial m₁(x) to produce a quotient q₁(x) and a remainder r₁(x). This operation can be expressed in mathematical for as

u(x)·x^{m}=q₁(x)·m₁(x)+r₁(x)

The quotient q₁(x) pre-multiplied by x^{m}, is then divided by minimal polynomial m₃(x) to produce a quotient q₂(x) and a remainder r₂(x). This operation can be expressed in mathematical for

q₁(x)·x^{m}=q₂(x)·m₃(x)+r₂(x)

The quotient q₂(x) pre-multiplied by x^{m}, is then divided by minimal polynomial m₅(x) to produce a quotient q₃(x) and a remainder r₃(x). This operation can be expressed in mathematical for

q₂(x)·x^{m}=q₃(x)·m₅(x)+r₃(x)

The division is continued t times and the during the t^{th} stage, The quotient qₜ₋₁(x) pre-multiplied by x^{m}, is then divided by minimal polynomial m₂ₜ₋₁(x) to produce a quotient qₜ(x) and a remainder rₜ(x). This operation can be expressed in mathematical for

qₜ₋₁(x)·x^{m}=qₜ(x)·m₂ₜ₋₁(x)+rₜ(x)

The division process can be summarized in mathematical form as described below

$$\begin{matrix}u ( x ) \cdot {x}^{( n - k )} = q ( x ) \cdot g ( x ) + r ( x ) \\ = ( ( ( ( {r}_{t} ( x ) \cdot {m}_{( 2 t - 3 )} ( x ) + {r}_{( t - 1 )} ( x ) \cdot {x}^{m} ) \cdot {m}_{( 2 t - 5 )} ( x ) ) \\ + {r}_{( t - 2 )} ( x ) \cdot {x}^{m} ) … {m}_{1} ( x ) ) + {r}_{1} ( x )\end{matrix}$$

The motivation for the above mathematical description of the division process can be easily seen by observing the mathematical equivalence of

r(x)=Rem(u(x)·x^{(n-k)})_{g(x)}

=Rem(u(x)·x^{mt})_{m1(x)·m3(x)·m5(x) . . . m(2t-1)(x)}

=Rem(u(x)·x^{m},x^{m},x^{m} . . . x^{m})_{m1(x),m3(x),m5(x) . . . m(2t-1)(x)}

The division process is expansion of the above equation in the form of successive division.

The desired r(x) is obtained by summing the weighted remainders r₁(x) through rₜ(x). The mathematical details are described as follows.

r(x)=((((rₜ(x)·m₍₂ₜ₋₃₎(x)+r₍ₜ₋₁₎(x)·x^{m})·m₍₂ₜ₋₅₎(x))+r₍ₜ₋₂₎(x)·x^{m}) . . . m₁(x))+r₁(x)

The mathematical equation that defines the remainder described in the above equation, forms the parity portion of the codeword, is described as follows. The remainder rₜ(x) that is obtained in the i^{th} division is multiplied by the minimal polynomial m₂ₜ₋₃(x). The result which is the partial product will have a length not exceeding 2·m. To this partial product the remainder rₜ₋₁(x) will be added upon adjusting the length from m to 2·m, with a pre-multiplication factor of x^{m}. This single multiplication and addition can be summarized as (rₜ(x)·m₍₂ₜ₋₃₎(x)+r₍ₜ₋₁₎(x)·x^{m}). This forms the new partial product, and will be multiplied by the minimal polynomial m₂ₜ₋₅(x) and added to the remainder r₍ₜ₋₂₎(x)·x^{2m}, which reflects the length adjustment by pre-multiplication by x^{2m}. The process of multiplication, pre-multiplication and polynomial addition continues until all the remainders are used.

Those who are skilled in the art of digital circuit design for BCH encoders, can readily appreciate that there is a controller that manages the timing, configuration selection, parameter selection and other operational details.

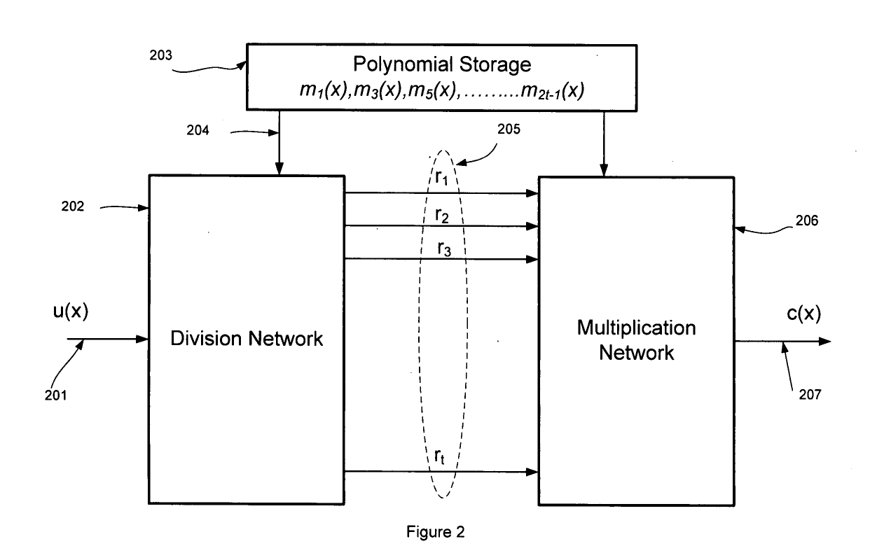

Referring to FIG. 2, illustrated is the division and multiplication process. Input message 201 enters the division network 202. The controller configures the value of t and chooses the proper minimal polynomials in the division network 202 through the bus 204. The minimal polynomials are stored in 203. The division process produces remainders 205 which form input to the multiplication network 206. The controller properly configures the multiplication network through the bus 204, to have the required values for the minimal polynomials. Upon the completion of the multiplication network, the parity bits are appended and the codeword 207 is transmitted as output.

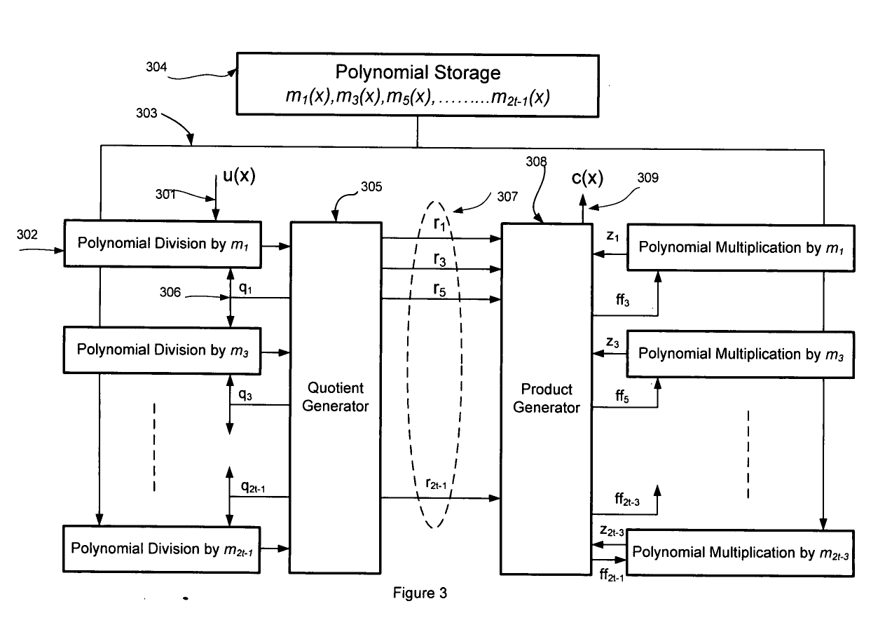

Referring to FIG. 3, illustrated is the division and multiplication process in greater detail. Minimal polynomials are stored in 304. They are written to the division and multiplication networks, under the command of a controller, using the bus 303. The message 301 enters the divider 310, through the quotient generator. Divider 310 is configured with divisor m₁(x). The quotient q₁(x), is formed in the quotient generator 305. The quotient q₁(x) enters the succeeding divider 311 as input and also enters the divider 310 as the feedback signal. Remainder r₁(x), generated by this divider 310 and the quotient generator 305 enters the product generator 308. Once the division is complete, all the remainders 307 enter the product generator 308. Remainder rₜ(x) is multiplied in the multiplier 312, which is configured with minimal polynomial m₂ₜ₋₃(x). The result, which is the partial product ff₂ₜ₋₃(x) forms the input to the multiplier 313, which is configured with polynomial m₂ₜ₋₅(x). The party sequence r(x) of sequence length m·t bits, leaves from the quotient generator 308, upon completion of the multiplication process. The division network, in a particular exemplary embodiment will be described in the following.

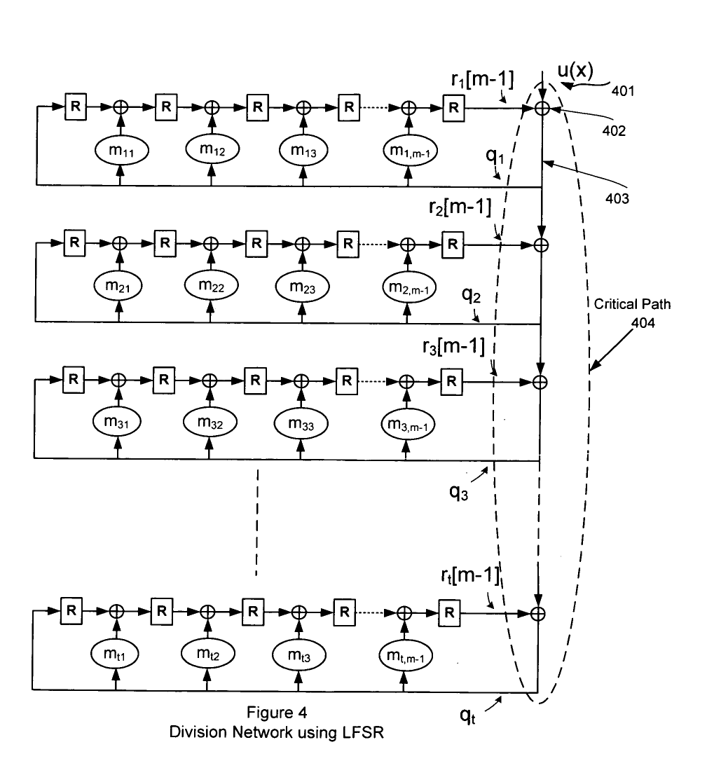

FIG. 4 refers to an exemplary embodiment of the division network and quotient generator network using LFSRs for polynomial division and XOR logic gates (404) for addition in the quotient generator. In this embodiment, the signals are configured by the controller to have a word length of 1. Equivalently, the exemplary embodiment is described as serial embodiment of the classical architecture. Quotient generator 404 is a network of XOR logic gates, connected in the ripple forward fashion. Each LFSR has m storage elements. The digital values in these storage elements form the remainder sequence upon the completion of the division process. The message u(x) enters the LFSR at the m^{th} storage element to be added to the content of this storage element in 402. Those who are skilled in the art of polynomial division using LFSR, can easily identify that this arrangement is equivalent to pre-multiplication by x^{m}. The quotient 403 enters the XOR that is next in the chain. In this arrangement, the division takes k clock cycles, which is exactly the same number of clock cycles taken by the classical BCH encoder architecture using long LFSR division. Feedback signals q₁(x), q₂(x), q₃(x), . . . qₜ(x) drive at most m number of XORs in the feedback path in each of the corresponding LFSR. This is the improvement of this invention, exemplified in this embodiment. Quotient qₜ(x) is generated using qₜ₋₁(x). This observation, termed as ripple effect of the quotient generator forms the critical path of this exemplary embodiment. The throughput or the clock period of this exemplary embodiment is determined by the total delay of the ripple chain of XOR logic gates. Arrangements to address throughput issues are described in later paragraphs, but first the multiplication network is described as follows.

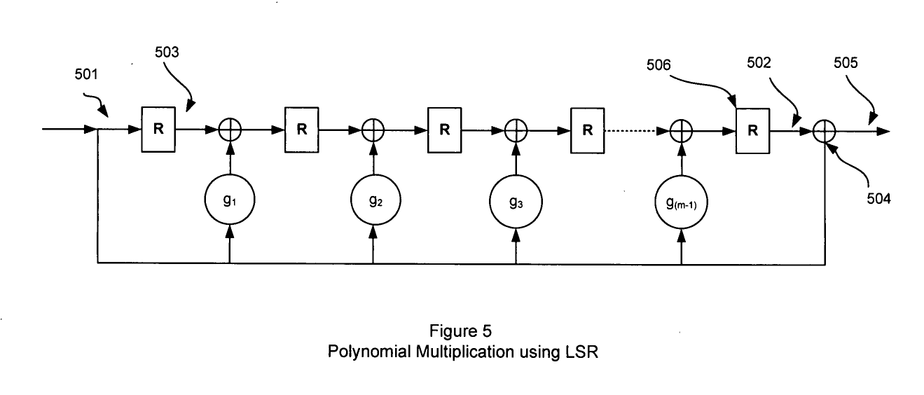

The building block of the multiplication network is the multiplier, very much like the divider being the building block of the divider network. The LFSR that is used for polynomial division can also be used for polynomial multiplication. Those who are skilled in the art of polynomial division and multiplication can easily see the pertinent modifications to the LFSR apparatus to deduce the apparatus for multiplication. FIG. 5 depicts such a multiplication network. One noticeable difference in the multiplication network is that there is no feedback signal driving the XOR gates, and hence there is no critical path for speed optimization at this building block level. Input to the multiplier 501 enters the first delay element 503 and simultaneously enters the XOR 504. In the XOR gate, the input 501 is added with the signal 502 stored in delay element 5046 to produce the signal 504 which is the product of the multiplication operation. This exemplary circuit embodiment is called a Linear Shift Register (LSR) based multiplier. Those who are well versed in the art of polynomial multiplication, can appreciate that there is no pre-multiplication operation and also that the sequence length of the output 505 can be bounded by the sum of the sequence lengths of the input 501 and the multiplier polynomial g. The multiplier network will be described next.

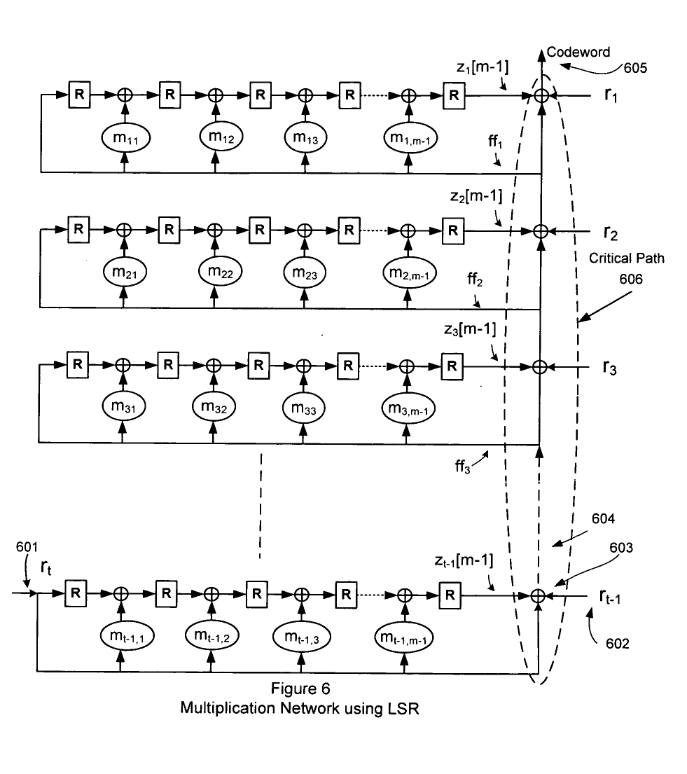

FIG. 6 depicts the multiplier network, in one exemplary embodiment of the invention that uses LSR as a multiplier building block, with input coming in serial stream and multiplication performed in serial fashion. All the LSR multipliers work simultaneously, with partial products leaving from (t−1)^{th} multiplier to the 1^{st} multiplier. There are (t−1) multipliers, and the controller configures the multipliers such that multiplier (t−1) is programmed with minimal polynomial m₂ₜ₋₃(x), multiplier (t−2) is programmed with m₂ₜ₋₅(x), so on until multiplier 1 is programmed with m₁(x). Remainder rₜ(x) 601 enters the multiplier (t−1) where it will be added in XOR 603 with remainder rₜ₋₁(x) and the signal stored in register element (m−1) to produce the partial product term ff₍ₜ₋₁₎ 604. Serial stream ff₍ₜ₋₁₎ forms the input data to the multiplier number (t−2), where it is multiplied with the minimal polynomial m₂ₜ₋₃(x) and then added to the remainder rₜ₋₂(x), generating the partial product ff₍ₜ₋₂₎. This exemplary embodiment of the invention takes (n−k) clock cycles to perform the multiplication operation. The parity bits 605 are tapped from the multiplier 1 as shown in the FIG. 6.

In this paragraph, several design examples are presented to highlight the differences among the classical method, method based on the CRT and the described invention. For a BCH code with t=11, m=11, k=1926, and n=2047, the present invention needs an XOR count of 121, classical architecture needs 121 XOR gates and the method based on CRT needs an XOR count of 1595. The critical path of the classical architecture has 121 XOR gates, and the critical paths in the CRT and the described invention have a maximum of 11 XOR gates. Here all the LFSRs and LSRs are assumed to be implemented in serial data flow with word size of 1 bit. In the case of DVB-S2/T2 with design parameters t=12, m=16, k=51648, and n=517840 the count of XOR gates for classical architecture is 192, those for CRT based method is 2506 and the count for the presented invention is 192. The critical path (feedback path) for the classical architecture has a load of 192, and the critical path in the feedback path for the method based on CRT and the presently described invention both have a load of a maximum of 16 XOR gates.

Turning to FIG. 6 again, which is an exemplary embodiment of the invention that implements the multiplication network with circuit apparatus, people who are well versed with digital circuit design can immediately appreciate that the critical path in the multiplication network is in the forward path which is highlighted as 606. The throughput or the clock period of the multiplication network is determined by the total delay in this critical path. The critical path 606 can be described as a ripple chain, where each adder is dependent on the output of the upstream adder. It an be immediately appreciated that the critical path in the division network in exemplary embodiment depicted in FIG. 4 is similar to the critical path depicted in FIG. 6, and measures similar to those that are taken to address the throughput and latency tradeoff for the forward path in the division network can be taken to optimize the critical path in the multiplier network also.

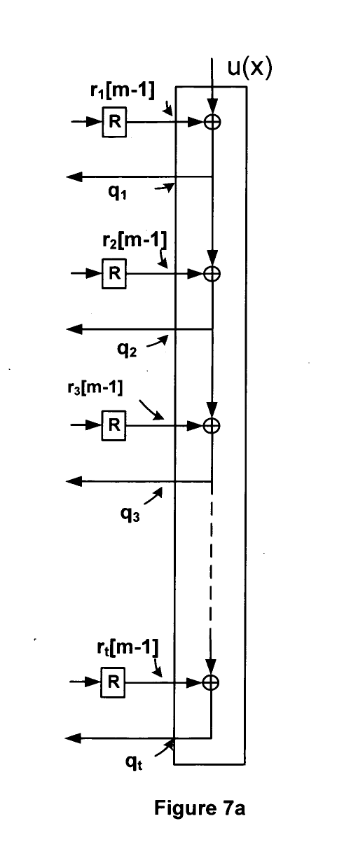

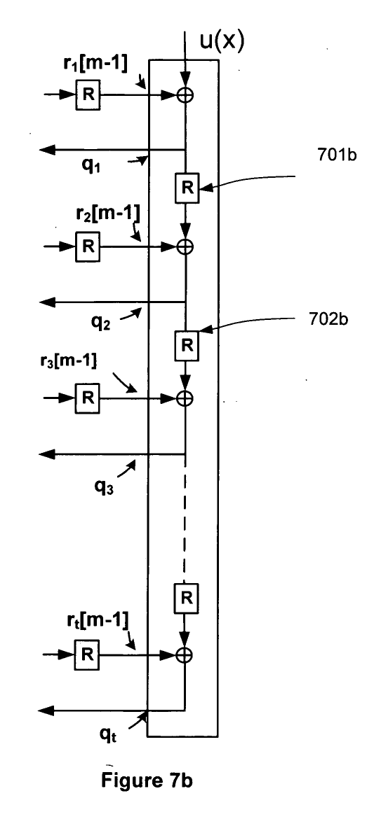

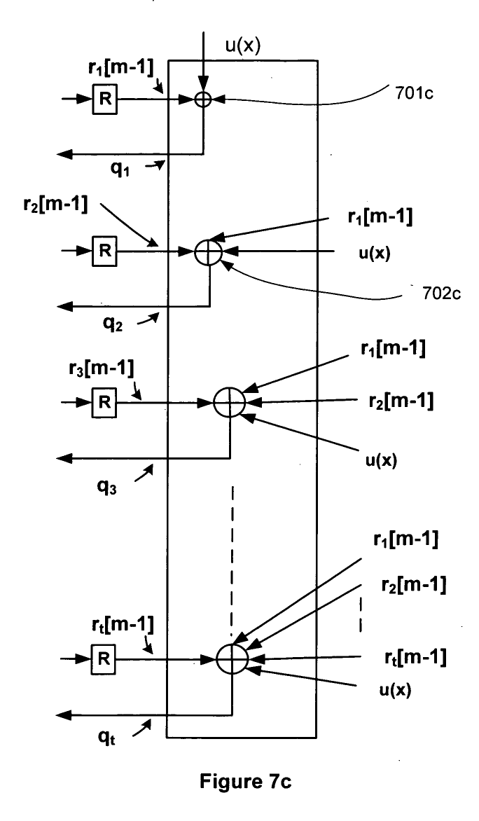

Referring to FIG. 7a, the critical path in the forward path of the division network is highlighted.

Those skilled in the design of VLSI circuits for DSP can readily appreciate that the longest path or the critical path in any architecture can be reduced by a suitable placement of pipeline registers in the critical path of the architecture. Those skilled in the art of VLSI design for DSP can further appreciate that the critical path can be the feedback path or the feed-forward path.

Referring to FIG. 7b, the pipeline registers 701b can be found in the forward path which are placed with the intention of reducing the critical path delay. The pipeline registers are placed between the quotient generated by an LFSR and the input XOR of the succeeding divider network. Those skilled in the art of VLSI design can readily appreciate that the latency of this particular embodiment increases by an equivalent amount of number of registers placed in the forward path, and in this particular embodiment, this increase is equal to t clock cycles. It can also be appreciated that the critical path is now reduced to the delay of one 2-input XOR. This is an embodiment where the throughput is maximized at the cost of increased latency.

Now referring to FIG. 7c, another embodiment for the tradeoff between throughput and latency can be found. In this embodiment the critical path is broken and the input to each divider is computed independently and no pipeline latches are placed. The input to each divider network is independently computed using the message u(x) and all the necessary signals r₁[m−1], r₂[m−1] . . . rₜ[m−1] that are available in the storage elements. It can be easily observed that the input size of the XOR gates for each divider increases from a value of 2 to t. Those who are skilled in the art of digital design can appreciate that the improvement achieved diminishes as the input size of the XOR increases.

Those who are skilled in the art of digital design can appreciate that there are embodiments that combine pipeline registers and independent input generation methods that are described in the above embodiments. Such an embodiment gives a tradeoff between the throughput and latency of the BCH encoder network.

In an embodiment, the BCH encoder can be programmed for different numerical values of t, which are the number of errors that can be corrected in the input block.

In an embodiment, the BCH encoder can be programmed such that, two or more but less than t minimal polynomials can be combined to form another polynomial of higher degree, and a suitable length for the LFSR will be configured accordingly.

In an embodiment, the BCH encoder can be configured so that the LFSR for each minimal polynomial can be further transformed using mathematical or circuit techniques such that the critical path is minimized.

In an embodiment, the BCH encoder can be configured such that the LFSR for each minimal polynomial can be retimed to minimize the critical path delay.

In an embodiment, the BCH encoder can be configured such that the LFSR for each minimal polynomial can be unfolded to accept parallel data or data word with size W, where W can be an integer >1.

In another embodiment, the BCH encoder can be configured such that one or all of the LFSRs are retimed and unfolded.

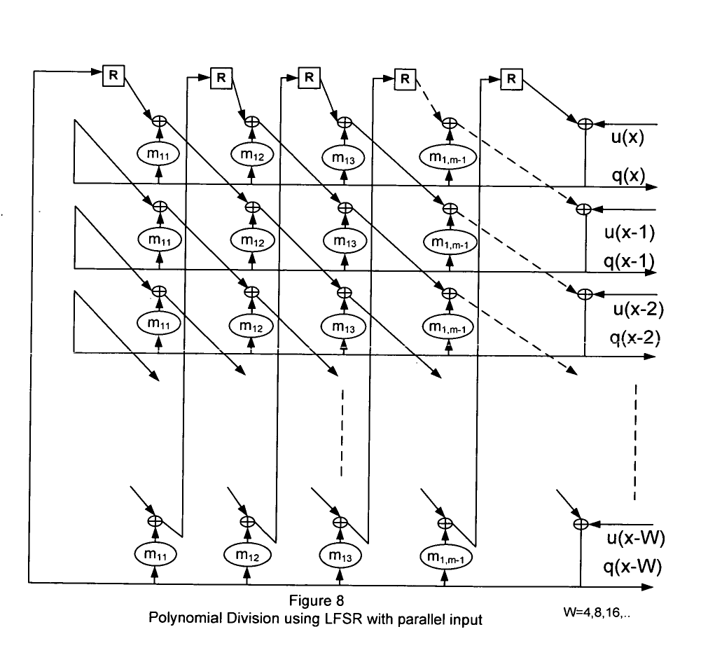

In yet another embodiment, the BCH encoder can be configured such that one or more or all of the LFSRs are simply unrolled to accept parallel data. A good reference for unrolling an LFSR is found in the work by R. Micheloni et al., mentioned in earlier paragraphs. An exemplary embodiment is shown in FIG. 8. The exemplary embodiment is used in the division network. The quotients are available as parallel that can be connected to the succeeding LFSR for further division.

Furthermore, in the above mentioned embodiment, the critical path in the feedback path can be minimized using mathematical or circuit techniques to increase the speed of operation.

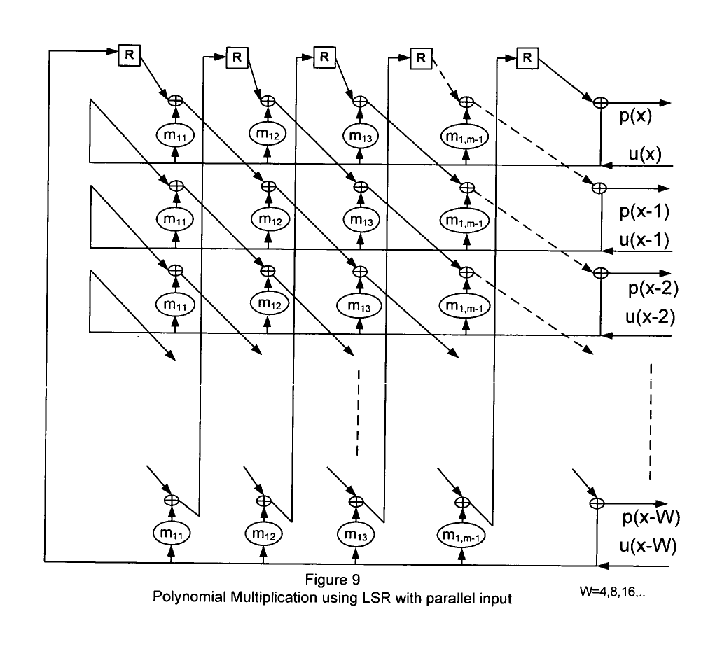

In an embodiment, the BCH encoder can be configured such that the shift registers employed for polynomial multiplication, are unrolled to accept parallel data. An exemplary embodiment is given in FIG. 9. The product term is available as a parallel word that can become an input for the succeeding stage.

In an embodiment, the division network and multiplication network are realized using the same LFSR. Those who are skilled in the art of polynomial division and multiplication can easily appreciate the changes that need to be performed to such a LFSR network.

In an embodiment, the invention described as an encoder can also be used as a syndrome generator in the decoder. Those who are skilled in the art of polynomial division, readily appreciate the merit and the necessary changes required.

### CONCLUSION

Although the invention has been described with reference to specific embodiments, this description is not meant to be construed in a limiting sense. Various modifications of the disclosed embodiments, as well as alternative embodiments of the invention, will become apparent to persons skilled in the art upon reference to the description of the invention. Any arrangement, which is designed to perform the same function for the same purpose, may be substituted for the specific embodiment shown in this disclosure. This application is intended to cover any variations and adaptations of the present invention. The invention is not limited to software implementation nor hardware implementation. The invention is not limited by the type of storage used for the minimal polynomials. The invention is not limited by the type of integrated circuit in which the present disclosure may be disposed. Nor is the invention limited to any specific type of process technology, e.g., CMOS, Bipolar, BiCMOS, GaAs, SiGe that may be used to manufacture the present disclosure. The invention is not limited by the channel through which the information exchange is performed, e.g., storage channel, wire-line channel or wireless channel. The invention is not limited to any specific method or apparatus that performs a tradeoff between latency and throughput. It is therefore contemplated that such modifications can be made without departing from the spirit or scope of the present invention as defined in the appended claims.

What is claimed is:

1. A method for encoding information according to a BCH code whose generator polynomial can be factored into t minimal polynomials, the method of encoding comprising of;
choosing the value of t and correspondingly choosing the t minimal polynomials;
dividing the polynomial representation of the information by first of the t minimal polynomials to produce the first quotient polynomial and the first remainder polynomial;
dividing the first quotient polynomial by the second of the t minimal polynomials to produce a second quotient polynomial and second remainder polynomial;
continuing the division until the (t−1)^{th} quotient polynomial is divided by the t^{th} minimal polynomial to produce the t^{th} quotient polynomial and t^{th} remainder polynomial;
sensing the information polynomial and the quotient polynomials and computing necessary feedback signals for a tradeoff between latency and throughput;
detection of the end of division process and initiating the process of multiplication and addition of remainder polynomials;
multiplication of the t^{th} remainder polynomial by the (t−1)^{th} minimal polynomial to produce the (t−1)^{th} product polynomial;
addition of the (t−1)^{th} remainder polynomial to the (t−1)^{th} product polynomial to produce the (t−1)^{th} intermediate codeword polynomial;
multiplication of the (t−1)^{th} intermediate codeword polynomial by the (t−2)^{nd} minimal polynomial to produce the (t−2)^{nd} product polynomial;
addition of the (t−2)^{nd} remainder polynomial to the (t−2)^{nd} product polynomial to produce the (t−2)^{nd} intermediate codeword polynomial;
sensing the intermediate codeword polynomials and the t^{th} remainder and computing the necessary inputs to the multipliers;
continuing the multiplication and addition process until the final codeword is obtained;

2. The said BCH code in claim 1 can be a binary code or a non-binary code.

3. One or all of the said minimal polynomials in claim 1 can be mathematically transformed to optimize the critical delay path in the feedback path.

4. Two or more but fewer than t minimal polynomials in claim 1 can be combined to produce another polynomial that is the least common multiple of the chosen minimal polynomials.

5. The feed-forward path in claim 1, can be retimed, unfolded or unrolled or a combination of any of the two operations, with the express intent of providing a trade-off between throughput and latency.

6. An apparatus for encoding information according to a BCH code whose generator polynomial can be factored into t minimal polynomials, the apparatus of encoding comprising of;
means for choosing the value of t and correspondingly choosing and storing the t minimal polynomials;
means for dividing the polynomial representation of the information by first of the t minimal polynomials to produce the first quotient polynomial and the first remainder polynomial;
means for dividing the first quotient polynomial by the second of the t minimal polynomials to produce a second quotient polynomial and second remainder polynomial;
continuing the division until the (t−1)^{th} quotient polynomial is divided by the t^{th} minimal polynomial to produce the t^{th} quotient polynomial and t^{th} remainder polynomial;
means for the detection of the end of division process and initiating the process of multiplication and addition of remainder polynomials;
means for the multiplication of the t^{th} remainder polynomial by the (t−1)^{th} minimal polynomial to produce the (t−1)^{th} product polynomial;
means for the addition of the (t−1)^{th} remainder polynomial to the (t−1)^{th} product polynomial to produce the (t−1)^{th} intermediate codeword polynomial;
means for the multiplication of the (t−1)^{th} intermediate codeword polynomial by the (t−2)^{nd} minimal polynomial to produce the (t−2)^{nd} product polynomial;
means for the addition of the (t−2)^{nd} remainder polynomial to the (t−2)^{nd} product polynomial to produce the (t−2)^{nd} intermediate codeword polynomial;
continuing the multiplication and addition process until the final codeword is obtained;

7. The said BCH code in claim 6 can be a binary code or a non-binary code.

8. The size of the input word in claim 6 can be any integer number greater than 1.

9. An apparatus in claim 6, wherein the division of polynomials comprises of a LFSR.

10. An apparatus in claim 6, wherein the multiplication of polynomials comprises of a LSR.

11. An apparatus in claim 6, wherein the division and multiplication of polynomials comprises of a LFSR.

12. An apparatus in claim 6, wherein the apparatus for addition is a gate of type XOR or XNOR.

13. One or all of the LFSRs in claim 11 can be mathematically transformed to optimize the critical delay path in the feedback path.

14. Two or more but fewer than t LFSRs in claim 11 can be combined to produce another LFSR that is the least common multiple of the chosen minimal polynomials.

15. The feed-forward path in claim 11, can be retimed, unfolded or unrolled or a combination of any of the two operations, with the express intent of providing a trade-off between throughput and latency.
